(19) United States
(12) Patent Application Publication
(10) Pub. No.: US 2009/0261317 A1
(43) Pub. Date: Oct. 22, 2009

(54) Enhancement of Light Emission Efficiency by Tunable Surface Plasmons

(76) Inventor: Roberto Paiella, Brookline, MA (US)

Correspondence Address: WEINGARTEN, SCHURGIN, GAGNEBIN & LEBOVICI LLP, TEN POST OFFICE SQUARE, BOSTON, MA, 02109, US

(21) Appl. No.: 11/991,568

(22) PCT Filed: Sep. 6, 2006
(86) PCT No.: PCT/US06/34573

§ 371 Date: Mar. 6, 2008

Related U.S. Application Data
(60) Provisional application No. 60/714,440, filed on Sep. 6, 2005.

(51) Int. Cl. H01L 33/00; H01L 21/28

(52) U.S. Cl. 257/13; 438/22; 257/E33.025; 257/E21.158

(57) ABSTRACT

An apparatus (275) and method of making a light emitting apparatus The light emitting apparatus (275) has a light emitting diode layer (285) and a stack of metal layers and dielectric layers (296) The metal layers may alternate with the dielectric layers The thickness of one or more metal layers determines a crossing pomt of one or more surface plasmon (SP) modes of one or more metal layers The thicknesses of the metal layer and dielectric layer control the size of an anticrossing of one or more SP modes of one or more metal layers.

### CROSS REFERENCE TO RELATED APPLICATIONS

This application claims benefit of U.S. Provisional Application No. 60/714,440, filed Sep. 6, 2005.

### TECHNICAL FIELD OF THE INVENTION

This invention generally relates to solid-state sources of ultraviolet, visible, and infrared radiation and more particularly to increasing an efficiency of emission of light by employing multiple layers of metal and dielectric to introduce tunable resonances.

### STATEMENT REGARDING FEDERALLY SPONSORED RESEARCH OR DEVELOPMENT

Not applicable.

### BACKGROUND OF THE INVENTION

Solid-state sources of visible light, such as semiconductor and organic light emitting diodes (LEDs), are a subject of considerable interest for many applications, including a goal of replacement of light bulbs for white lighting. Towards this goal, several techniques have been investigated to enhance both their internal quantum efficiency and their light extraction efficiency.

An approach that has attracted attention is a use of surface plasmons (SPs) to increase the radiative recombination rate. SPs are collective charge oscillations at an interface between a metal layer and a dielectric layer; a coupling of light to these collective charge oscillations results in guided polariton modes that are confined at, and propagate along, the interface. Due to a tightly-bound nature of these modes, their fields near the interface are highly enhanced compared to radiative modes. Thus, in a device, if a metal layer is deposited in close proximity of a light emitting diode (LED) layer, the quantum efficiency of the device is correspondingly increased through an emission of SP polaritons at a surface of the metal layer. These guided polariton modes can then be converted into radiative waves, or a useful output of the LED, by including a grating, or merely by the roughness of the surface of the metal layer.

FIG. 1(a) illustrates a prior art structure and plots of Energy changing with Wavevector for the prior art structure. Wavevector equals (2π/wavelength). Dispersion plots ω(k)—where k is the in-plane wavevector—of the bound SP polaritons of the structure are also shown, for a silver (Ag) layer 120 having a thickness of (i) 100 nm (solid-lined plot, or plot 130), (ii) 10 nm (dashed-lined plot, or plot 135), and (iii) 5 nm (dotted-lined plot, or plot 140). The dash-dotted straight line 145 is the light line in a GaN (LED) layer 125. The silver layer 120 is between the GaN layer 125 and an air layer 115. A single silver layer 120, which is a single metal layer, does not allow a tuning of an SP resonance frequency. The upper set of plots is for a silver layer 120/air layer 115 interface. The lower set of plots is for a GaN layer 125/silver layer 120 interface.

The SP dispersion plots ω(k) featured in FIG. 1(a) are for different thicknesses of the silver layer 120. These are computed by solving Maxwell's equations in the GaN layer 125, silver layer 120, and air layer 115, and matching the solutions with electromagnetic boundary conditions. A simple Drude model is used for the dielectric function of silver layer 120, i.e., ε(ω)=ε_{∞}(1−ωₚ²/(ω²+iγω)), with ωₚ=3.76 eV and ε_{∞}=9.6 extrapolated from experimental data (γ, or the damping rate, is sufficiently small to have a negligible effect on the SP dispersion). For each thickness of the silver layer 120, two dispersion plots are obtained, one (at lower frequencies) for the SPs at the GaN/silver (125/120) interface, the other for the SPs at the silver/air (120/115) interface. As layer thickness is decreased, the solutions at the two interfaces couple to each other leading to symmetric and anti-symmetric hybrid modes, and correspondingly a frequency separation between the two dispersion plots increases.

A simple figure of merit that can be used to quantify the SP-induced LED efficiency enhancement is the radiative recombination rate ratio,

$${F}_{r} ( ℏ ω ) = \frac{{Γ}_{0} ( ℏ ω ) + {Γ}_{S P} ( ℏ ω )}{{Γ}_{0} ( ℏ ω )} , \qquad ( 1 )$$

where Γ₀ and Γ_{SP} are the spontaneous emission rates into radiation modes and SP polaritons, respectively (Fᵣ is the same as the Purcell factor in the limit of negligible nonradiative recombination). Γ_{SP} can be calculated using Fermi golden rule,

$${Γ}_{S P} ( ℏ ω ) = \frac{2 π}{ℏ} {\vert d \cdot {E}_{act} ( ℏ ω ) \vert}^{2} [ \frac{A}{4 π} \frac{d ( {k}^{2} )}{d ( ℏ ω )} ] , \qquad ( 2 )$$

where d is the dipole moment matrix element, which will be assumed to be isotropic for simplicity; the quantity in brackets is an SP density of states (SP-DOS) on a surface of area A; and E_{act}(ω) is the electric field of the SP mode of frequency ω, normalized to a vacuum fluctuation energy ω/2, and evaluated at a location of the active layer. To compute E_{act}(ω), a separation of 10 nm between an active layer, e.g., of an InGaN quantum well (not shown), and the silver layer 120, e.g., due to a GaN cap layer, has been used in generating all of the plots of FIGS. 1(a) and 1(b). Finally, Γ₀ is computed using the classical formula

$${Γ}_{0} ( ℏ ω ) = \frac{4 {nd}^{2} {ω}^{3}}{3 ℏ {c}^{3}} , \qquad ( 3 )$$

where n is the refractive index of an emissive material.

This model of Equs. (1), (2), and (3) is based on several simplifying assumptions, and it does not account for the complexities of semiconductor active layers, and for the broadening of Γ_{SP}(ω) due to damping of the electronic motion in the metal. On the other hand, it has the advantage of requiring a minimal set of input parameters and thus it provides a very convenient design tool. In fact, after substitution of Equs. (2) and (3) into (1), Fᵣ only depends on the layers' dielectric functions and thicknesses through E_{act} and ω(k). From a device perspective, the more important parameters are the LED internal efficiency with and without SP enhancement. These are given by η=(Γ₀+Γ_{SP})/(Γ₀+Γ_{SP}+Γ_{NR}) and η₀=Γ_{NR}) respectively, where Γ_{NR} is the nonradiative recombination rate and unit probability of SP conversion into radiation modes has been assumed. Eliminating Γ_{NR} from these two expressions and using Equ. (1) yields

$${F}_{r} = \frac{η}{1 - η} \frac{1 - {η}_{0}}{{η}_{0}} . \qquad ( 4 )$$

Thus, for example, a value of Fᵣ=100 corresponds to an efficiency enhancement from η₀=10% to η=92%, or from η₀=50% to η=99%, and so forth.

FIG. 1(b) shows calculated plots of radiative recombination rate ratio (Fᵣ) changing with Energy (eV). These plots correspond to the GaN layer 125/silver layer 120 interface as described in the description of FIG. 1(a). As shown by the plot 130, for a thick (100-nm) silver layer 120, Fᵣ reaches a maximum value of ≈160 near the asymptotic energy ω_{SP}(≈2.9 eV for silver on GaN), where the SP-DOS diverges. At energies above ω_{SP}, the interface no longer supports SP guided modes and as a result Fᵣ sharply decreases to unity. At lower energies, a gradual reduction is observed, due to the increasing slope of the dispersion plot ω(k)—and hence decreasing SP-DOS—with decreasing energy. If a thinner silver layer 120 is used, the dispersion plot of the SPs at the GaN layer 125/silver layer 120 interface is pushed to lower energies by a coupling with the SPs at the silver layer 120/air layer 115 interface (while the asymptotic energy ω_{SP} remains unchanged), and correspondingly the spectrum of Fᵣ is broadened. Thus, as shown by the plot 140 and the plot 135 in FIG. 1(b), thinner metal layers can be used to increase the efficiency enhancement at energies below ω_{SP}. However, this approach only leads to a modest gain in the SP-DOS and hence in Fᵣ, and therefore it is not effective in tuning the SP resonance.

Some enhancements in the photoluminescence efficiency have been demonstrated in silver-coated organic and GaN devices based on SP-mediated light emission. However, for this approach to be effective the LED emission frequency should be closely matched to an SP resonance frequency ω_{SP}, where the SP-DOS is maximum. For a single planar metallic overlayer, this frequency is determined by dielectric functions of the metal and emitter material. If an emission frequency differs from ω_{SP}, an enhancement in the SP efficiency is reduced. Thus, the development of SP-enhanced LEDs will require a technique to effectively tune the SP resonance frequency to the emission frequency of a given device. The resonance frequency is the frequency where the SP-DOS, and hence the radiative recombination rate ratio Fᵣ, is maximum.

A possible technique is the use of a metallic grating, instead of a planar film or a planar layer, to break up an SP dispersion relation into a series of bands. Through a careful choice of the metallic grating period, this can lead to a band edge—and hence an increased SP-DOS—in the wavelength region of interest. Tunable SPs have also been demonstrated using metallic nanospheres and nanoshells, whose geometry allows for a wide tuning range. However, these approaches require a precise control of the metal features, size and shape, leading to a demanding fabrication process.

### BRIEF SUMMARY OF THE INVENTION

A light emitting apparatus has a light emitting diode layer and a stack of metal layers and dielectric layers. The metal layers may alternate with the dielectric layers. There may be several metal layers or several dielectric layers together. The thickness of one or more metal layers is selected to be of such a size to determine a crossing point of one or more surface plasmon (SP) modes of one or more metal layers. Further, the thicknesses of the metal layer and one or more dielectric layers are selected to be of such dimensions to control the size of an anticrossing of one or more surface plasmon modes of one or more metal layers. That is, the SP resonance frequency (the optical frequency of maximum light-emission efficiency enhancement) can be tuned by using a stack of metal and dielectric layers and by varying the thicknesses of these layers.

### BRIEF DESCRIPTION OF THE SEVERAL VIEWS OF THE DRAWINGS

FIG. 1(a)—A prior art structure and plots of Energy changing with Wavevector, i.e., dispersion curves, for the prior art structure.

FIG. 1(b)—Plots of radiative recombination rate ratio (Fᵣ) changing with Energy (eV) for the prior art structure shown in FIG. 1(a).

FIG. 2(a)—Plots of Energy changing with Wavevector, i.e., dispersion curves, of the bound SP polaritons of the inventive light emitting apparatus 275 for a first set of thicknesses of layers of the light emitting apparatus.

FIG. 2(b)—Plots of Energy changing with Wavevector, i.e., dispersion curves, of the bound SP polaritons of the inventive light emitting apparatus 275 for a second set of thicknesses of layers of the light emitting apparatus.

FIG. 2(c)—The light emitting apparatus according to a first embodiment of the invention.

FIG. 3—Plots of radiative recombination rate ratio (Fᵣ) changing with Energy for several stacks of the light emitting apparatus.

FIG. 4—A flowchart describing a method to make the light emitting apparatus according to the first embodiment of the invention.

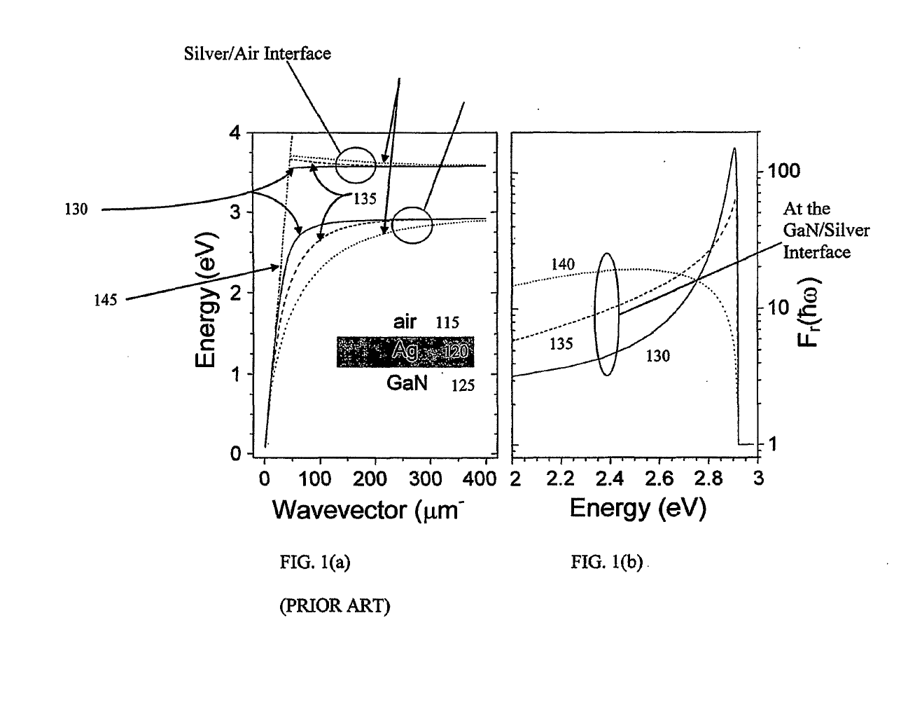

### DETAILED DESCRIPTION OF THE INVENTION

This invention relates to an apparatus and a method, based on coupled SPs in multiple metal layers separated by dielectric layers. By selecting a thickness of one or more of the metal layers and dielectric layers, the invention generates a tunable singularity in the SP-DOS, through a hybridization and an anticrossing of SP dispersion plots of an interface in proximity. The invention engineers the SP-DOS in a novel manner.

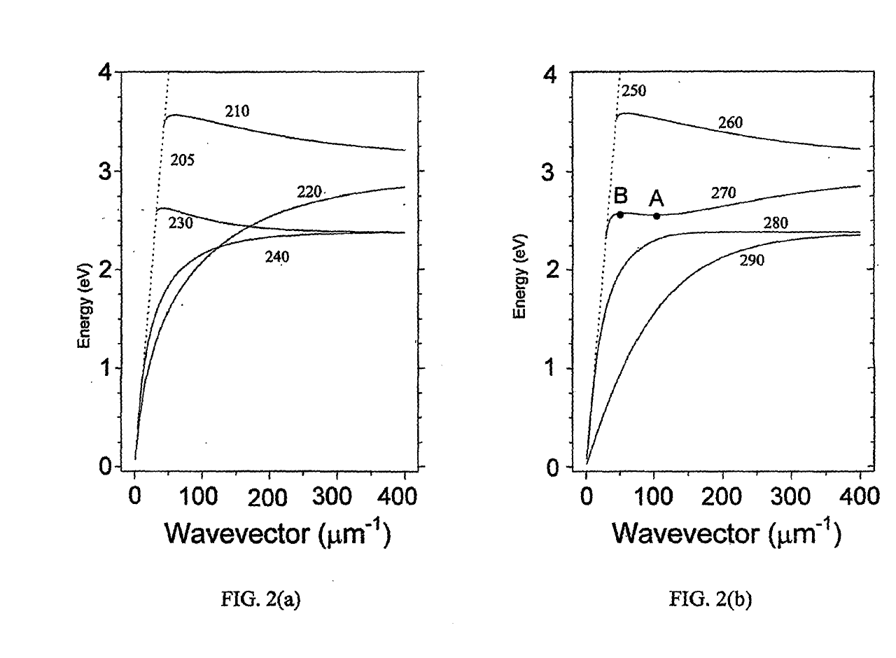

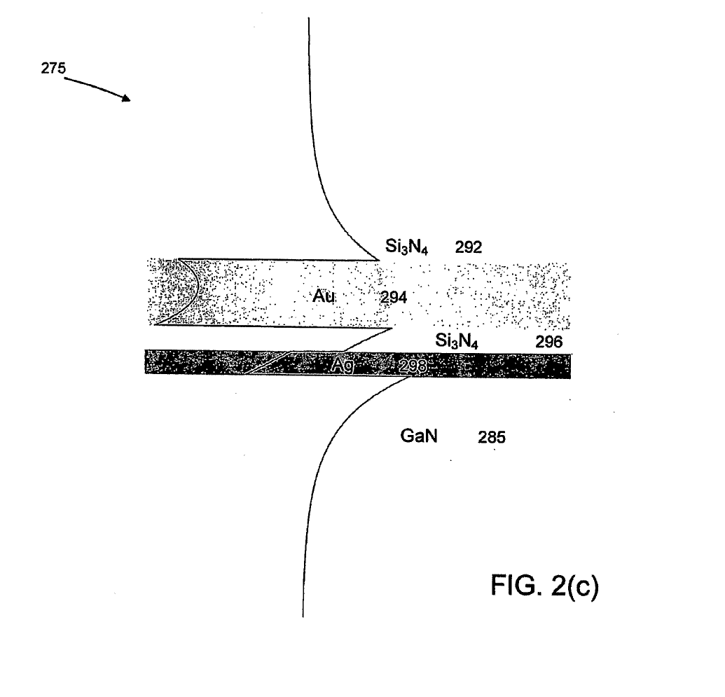

Significant enhancements at tunable photon energies are obtained by a use of multiple metal layers interspersed with dielectric layers. An objective is to introduce singularities in the SP-DOS at the energies of interest through the anticrossing of SP modes of different metal layers. The structure of a light emitting apparatus 275, shown in FIG. 2(c), is made with a first metal (5 nm silver) layer 298 deposited over an LED layer 285, followed by a second metal (14 nm Au) layer 294 sandwiched between a first dielectric layer 296 and a second dielectric layer 292. This structure contains four metallo-dielectric interfaces and, therefore, supports four SP branches, plotted in FIGS. 2(a) and 2(b) for a thickness of the first dielectric layer 296 of 100 nm and 5 nm, respectively (ωₚ=2.87 eV and ε_{∞}=8.9 for Au were used in these calculations). In order of increasing asymptotic energy, these SP branches are associated with the two Au/Si₃N₄ interfaces (namely, 294/292 and 294/296), the Ag/GaN interface (298/285), and the Ag/Si₃N₄ interface (298/296), respectively. In the preceding sentence, only reference numerals have been used, instead of the full layer name and the corresponding reference numeral, to describe the interfaces for the sake of brevity.

FIG. 2(a) shows plots of Energy changing with Wavevector, i.e., dispersion curves, of the bound SP polaritons of the light emitting apparatus for a first set of thicknesses of layers of the structure. These plots illustrate dispersion behavior of the bound SP polaritons of the light emitting apparatus 275 shown in FIG. 2(c). The thicknesses of the silver layer 298/Si₃N₄ layer 296/gold 294 layers are 5 nm/100 nm/14 nm respectively.

FIG. 2(b) shows plots of Energy changing with Wavevector, i.e., dispersion curves, of the bound SP polaritons of the light emitting apparatus for a second set of thicknesses of layers of the light emitting apparatus. These plots illustrate dispersion behaviour of the bound SP polaritons of the light emitting apparatus 275 shown in FIG. 2(c). The thicknesses of the silver layer 298/Si₃N₄ layer 296/gold layer 294 are 5 nm/5 nm/14 nm.

In FIG. 2(b), points A and B denote the tunable singularities. A singularity in the SP density of states occurs whenever the SP dispersion relation (i.e., SP Energy versus Wavevector) has a zero slope, such as at points A and B of FIG. 2(b). The corresponding frequency is the SP resonance frequency. Attaining tunable singularities means being able to tune this SP resonance frequency, which can be done with light emitting apparatus 275 by varying the thicknesses of various layers.

In FIGS. 2(a) and 2(b), both the GaN (LED) layer 285 and the Si₃N₄ layer 292 (an overlayer) are taken to be infinitely thick. The LED is typically made of a top GaN spacer layer (not shown), an underlying active layer (e.g., an InGaN quantum well, not shown), and an underlying substrate (not shown). The dotted straight line in each of these two figures, i.e., line 205 in FIG. 2(a) and line 250 in FIG. 2(b), is a light line in a GaN layer 285.

In FIG. 2(a), the first dielectric layer 296 between the two metal layers is, thick relative to an SP decay length in Si₃N₄. Thus, the SP modes of the first metal layer 298 and the second metal layer 294 are essentially uncoupled from each other and their dispersion plots can cross. Vice versa, in FIG. 2(b), the fields of these modes strongly overlap through the first dielectric layer 296, leading to a hybrid solution near a crossing point. Therefore, an anticrossing behavior is observed which causes a flattening of the dispersion plots 270 and 280, and hence singularities in the SP-DOS (proportional to dk/dω), on both sides of the anticrossing. At the point labeled A in the FIG. 2(b), this singularity is also accompanied by a relatively large SP field at the LED layer 285. A transverse component of the relatively large SP field is a vector component of an electric field perpendicular to metal-dielectric interfaces. Thus, according to Equs. (1) and (2), Fᵣ is expected to be large in a spectral vicinity of point A. This spectral region can be tuned over a wide range by varying the metal thicknesses, which determine a location of the crossing point, and a thickness of the first dielectric layer 296, which determines a size of the anticrossing.

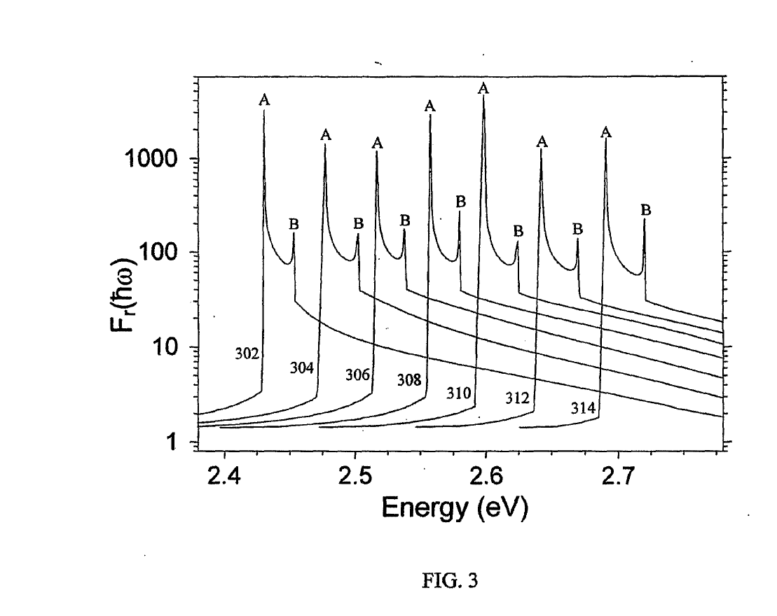

A calculated plot of Fᵣ for the light emitting apparatus 275 of FIG. 2(c) is plotted in FIG. 3 (fourth plot from the left or plot 308). FIG. 3 shows plots 302, 304, 306, 308, 310, 312, and 314 of the radiative recombination rate ratio (Fᵣ) changing with Energy for several dimensions of the light emitting apparatus 275. Two sharp peaks are observed in this plot, corresponding to the points A and B in FIG. 2(b)—the latter being another point of singular SP-DOS and, in the presence of coupling, of sizable SP field at the LED layer 285. In the spectral region of these two peaks, Fᵣ remains large over a range of several 10 s of meV; for example, if averaged over an LED bandwidth of 100 meV, the maximum value of Fᵣ is 79, corresponding to an increase in internal efficiency from, e.g., 10% to 90% according to Equ. (4). Experimentally, the plots of Fᵣ will be broader than these plots by several 10 s of meV due to ohmic losses in metal. However, the above efficiency enhancement integrated over a wide bandwidth will not be significantly altered by such a broadening.

To illustrate the tunability allowed by this approach, the other plots in FIG. 3 correspond to the same light emitting apparatus 275 but with different values of the thickness of the various layers of the light emitting apparatus 275 as tabulated in Table 1 below:

TABLE 1

| | First Metal Layer | First Dielectric | Second Metal |
|---|---|---|---|
| Plot | (Ag) Thickness | Layer Thickness | Layer (Ag) |
| Number | (nm) | (nm) | Thickness (nm) |
| 302 | 4 | 9 | 25 |
| 304 | 4 | 7 | 20 |
| 306 | 5 | 6 | 17 |
| 308 | 5 | 5 | 14 |
| 310 | 5 | 4 | 11 |
| 312 | 6 | 4 | 9 |
| 314 | 6 | 4 | 6 |

As shown, a tuning range of at least 300 meV is covered, with similar plots of Fᵣ, and at energies removed from the asymptotic SP energies of both the LED layer 285/first metal layer 298 interface and a possible GaN/gold(Au) interface (≈2.9 eV and 2.2 eV, respectively). Various other wavelength regions of interest can be similarly accessed using different dielectrics and/or metals. More complex structures—e.g., involving more than two metallic layers—can also be designed to further optimize the SP-DOS for LED efficiency enhancement or other applications.

Next, the coupling of emitted SP polaritons into radiation modes is described. Light can be extracted quite efficiently from the SPs by a sub-micron roughness on a metal surface. Similar results can be expected with intentionally introduced roughness in the second dielectric layer 292. A more reliable method is a use of a grating in the first metal layer 298, or the second metal layer 294, or the second dielectric layer 292. While the grating can also be used to tune the SP resonance, one advantage of the present invention is that no stringent condition is imposed on a period of the grating. This could significantly simplify a fabrication of the light emitting apparatus 275; alternatively, the grating may be designed to separately optimize a directionality of an emitted beam and hence maximize the efficiency of LED light extraction.

The light emitting apparatus 275, according to a first embodiment of the invention, has a layered structure. Over a light emitting diode layer 285 (a GaN layer here), there is a first metal layer 298 having a thickness, a first surface, and a second surface; next above is a first dielectric layer 296 having a thickness, a first surface, and a second surface; next above is a second metal layer 294 having a thickness, a first surface and a second surface; next above is a second dielectric layer 292 having a thickness, a first surface, and a second surface. The first surface of the first metal layer 298 is in contact with the light emitting diode layer 285; the second surface of the first metal layer 298 is in contact with the first surface of the first dielectric layer 296; the first surface of the second metal layer 294 is in contact with the second surface of the first dielectric layer 296; the second surface of the second metal layer 294 is in contact with the first surface of the second dielectric layer 292; and the second surface of the second dielectric layer 292 in contact with a gas. One or more of the thickness of the first metal layer 298 and the thickness of the second metal layer 294 is configured to determine a crossing point of one or more of a surface plasmon mode of the first metal layer 298 and a surface plasmon mode of the second metal layer 294, and the thickness of the first dielectric layer 296 is configured to determine the size of the anticrossing of the surface plasmon mode of the first metal layer 298 and the surface plasmon mode of the second metal layer 294. Stated differently, the light emitting apparatus 275 permits the SP resonance frequency, i.e., an optical frequency of a maximum light-emission efficiency enhancement, to be tuned by using a stack of metal and dielectric layers and by varying the thicknesses of these metal and dielectric layers.

Though the light emitting apparatus 275 disclosed has a metal layer sandwiched between two dielectric layers, a person having an ordinary skill in the art would appreciate that such an order of sandwiching could differ in a different embodiment.

The light emitting apparatus 275 may have one pair of a metal layer and a dielectric layer in contact with the second surface of the second dielectric layer 292, and the metal layer and the dielectric layer may include a grating. Further, light emitting apparatus 275 may have a tunable resonance of the surface plasmon mode, the tunable resonance may match a light frequency, and the resonance of the surface plasmon mode is tunable independent of a material of various layers, namely, the first metal layer 298, the second metal layer 294, the first dielectric layer 296, and the second dielectric layer 292. Similarly, the resonance of the surface plasmon mode may be tunable independent of a material selected for a layer in the pair including a metal layer and a dielectric layer.

As a person having an ordinary skill in the art would appreciate, in the light emitting apparatus 275, the first metal layer 298 may be made of silver, the first dielectric layer 296 may be made of Si₃N₄, the second metal layer 294 may be made of gold, the second dielectric layer 292 may be made of Si₃N₄, and the light emitting diode layer 285 may be made of GaN.

In the light emitting apparatus 275, the thickness of the first dielectric layer 296 may be adjusted to generate a tunable singularity in a surface plasmon density of a state. Further, a grating may be included in any of the layers, namely, the first metal layer 298, the first dielectric layer 296, the second metal layer 294, and the second dielectric layer 292.

In a second embodiment of the present invention, the light emitting apparatus 275 may have a single or a multiple quantum-well design or even be a bulk.

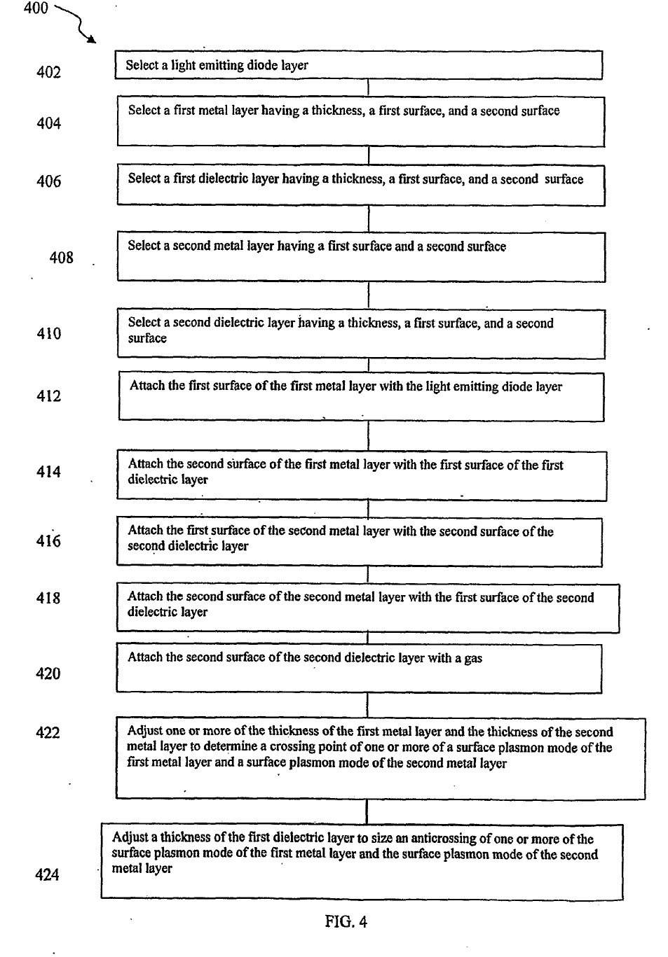

FIG. 4 describes the steps of a method 400 of fabricating the light emitting apparatus 275. At step 402, a light emitting diode layer 285 is selected; at step 404, a first (silver) metal layer 298 having a thickness, a first surface, and a second surface is selected; at step 406 a first dielectric layer having a thickness, a first surface, and a second surface; at step 408, a second metal layer 294 having a thickness, a first surface, and a second surface is selected; at step 410, a second dielectric layer 292 having a thickness, a first surface, and a second surface is selected; at step 412, the first surface of the first metal layer 298 is attached with the light emitting diode layer 285; at step 414, the second surface of the first metal layer 298 is attached with the first surface of the first dielectric layer 296 attached; at step 416, the first surface of the second metal layer 294 is attached with the second surface of the first dielectric layer 296; at step 418, the second surface of the second metal layer 294 is attached with the first surface of the second dielectric layer 292; at step 420, the second surface of the second dielectric layer 292 is attached with a gas; at step 422, one or more of the thickness of the first metal layer 298 and the thickness of the second metal layer 294 is adjusted to determine a crossing point of one or more of a surface plasmon mode of the first metal layer 298 and a surface plasmon mode of the second metal layer 294; and at step 424, a thickness of the first dielectric layer 296 is adjusted to size an anticrossing of one or more of the surface plasmon mode of the first metal layer 298 and the surface plasmon mode of the second metal layer 294.

What is claimed is:

1. A light emitting apparatus, the apparatus comprising:
a light emitting diode layer;
a first metal layer having a thickness, a first surface, and a second surface;
a first dielectric layer having a thickness, a first surface, and a second surface;
a second metal layer having a thickness, a first surface and a second surface;
a second dielectric layer having a thickness, a first surface, and a second surface;
the first surface of the first metal layer in contact with the light emitting diode layer;
the second surface of the first metal layer in contact with the first surface of the first dielectric layer;
the first surface of the second metal layer in contact with the second surface of the first dielectric layer;
the second surface of the second metal layer in contact with the first surface of the second dielectric layer;
the second surface of the second dielectric layer in contact with a gas;
one or more of the thickness of the first metal layer and the thickness of the second metal layer configured to determine a crossing point of one or more of a surface plasmon mode of the first metal layer and a surface plasmon mode of the second metal layer; and
the thickness of the first dielectric layer configured to size an anticrossing of one or more of the surface plasmon mode of the first metal layer and the surface plasmon mode of the second metal layer.

2. The apparatus of claim 1 wherein at least one pair of a metal layer and a dielectric layer is in contact with the second surface of the second dielectric layer.

3. The apparatus of claim 2 wherein each of the metal layer and the dielectric layer, in the at least one pair of a metal layer and a dielectric, includes a grating.

4. The apparatus of claim 1 wherein a resonance of the surface plasmon mode is tunable.

5. The apparatus of claim 4 wherein the resonance of the surface plasmon mode is tunable to match a light frequency.

6. The apparatus of claim 4 wherein the resonance of the surface plasmon mode is tunable independent of a material of a layer selected from the group consisting of:
the first metal layer,
the second metal layer,
the first dielectric layer, and
the second dielectric layer.

7. The apparatus of claim 4 wherein the resonance of the surface plasmon mode is tunable independent of a material selected for a layer in the at least one pair of a metal layer and a dielectric layer.

8. The apparatus of claim 1 wherein the first metal layer is silver.

9. The apparatus of claim 1 wherein the first dielectric layer is Si₃N₄.

10. The apparatus of claim 1 wherein the second metal layer is gold.

11. The apparatus of claim 1 wherein the second dielectric layer is Si₃N₄.

12. The apparatus of claim 1 wherein the thickness of the first dielectric layer is adjusted to generate a tunable singularity in a surface plasmon density of a state.

13. The apparatus of claim 1 wherein the light emitting diode layer is GaN.

14. The apparatus of claim 1 wherein the first metal layer includes a grating.

15. The apparatus of claim 1 wherein the first dielectric layer includes a grating.

16. The apparatus of claim 1 wherein the second metal layer includes a grating.

17. The apparatus of claim 1 wherein the second dielectric layer includes a grating.

18. The apparatus of claim 1 wherein the apparatus has a quantum-well design.

19. The apparatus of claim 1 wherein the first metal layer is in contact with at least a third metal layer.

20. The apparatus of claim 1 wherein the second metal layer is in contact with at least a fourth metal layer.

21. The apparatus of claim 1 wherein the first dielectric layer is in contact with at least a third dielectric layer.

22. The apparatus of claim 1 wherein the second dielectric layer is in contact with at least a fourth dielectric layer.

23. A method of fabricating a light emitting apparatus, the method comprising:
selecting a light emitting diode layer;
selecting a first metal layer having a thickness, a first surface, and a second surface;
selecting a first dielectric layer having a thickness, a first surface, and a second surface;
selecting a second metal layer having a thickness, a first surface, and a second surface;
selecting a second dielectric layer having a thickness, a first surface, and a second surface;
attaching the first surface of the first metal layer with the light emitting diode layer;
attaching the second surface of the first metal layer with the first surface of the first dielectric layer;
attaching the first surface of the second metal layer with the second surface of the second dielectric layer;
attaching the second surface of the second metal layer with the first surface of the second dielectric layer;
attaching the second surface of the second dielectric layer with a gas;
adjusting one or more of the thickness of the first metal layer and the thickness of the second metal layer to determine a crossing point of one or more of a surface plasmon mode of the first metal layer and a surface plasmon mode of the second metal layer; and
adjusting the thickness of the first dielectric layer configured to size an anticrossing of one or more of the surface plasmon mode of the first metal layer and the surface plasmon mode of the second metal layer.
